(19) United States
(12) Patent Application Publication
(10) Pub. No.: US 2010/0111808 A1
(43) Pub. Date: May 6, 2010

(54) GROUP-III NITRIDE MONOCRYSTAL WITH IMPROVED CRYSTAL QUALITY GROWN ON AN ETCHED-BACK SEED CRYSTAL AND METHOD OF PRODUCING THE SAME

(75) Inventors: Siddha Pimputkar, Goleta, CA (US); Derrick S. Kamber, Goleta, CA (US); Makoto Saito, Tsukuba (JP); Steven P. DenBaars, Goleta, CA (US); James S. Speck, Goleta, CA (US); Shuji Nakamura, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 12/612,477

(22) Filed: Nov. 4, 2009

Related U.S. Application Data
(60) Provisional application No. 61/111,644, filed on Nov. 5, 2008.

(51) Int. Cl. C30B 25/00; C01B 21/06

(52) U.S. Cl. 423/409; 117/106; 117/84

(57) ABSTRACT

The present invention provides a method for growing group III-nitride crystals wherein the group III-nitride crystal growth occurs on an etched seed crystal. The etched seed is fabricated prior to growth using a temperature profile which produces a high solubility of the group III-nitride material in a seed crystals zone as compared to a source materials zone. The measured X-ray diffraction of the obtained crystals have significantly narrower Full Width at Half Maximum values as compared to crystals grown without etch back of the seed crystal surfaces prior to growth.

### CROSS REFERENCE TO RELATED APPLICATIONS

This application claims the benefit under 35 U.S.C. Section 119(e) of co-pending and commonly-assigned application:

U.S. Provisional Application Ser. No. 61/111,644, filed on Nov. 5, 2008, by Siddha Pimputkar, Derrick Kamber, Makoto Saito, Steven P. DenBaars, James S. Speck and Shuji Nakamura, entitled “GROUP-III NITRIDE MONOCRYSTAL WITH IMPROVED CRYSTAL QUALITY GROWN ON AN ETCHED-BACK SEED CRYSTAL AND METHOD OF PRODUCING THE SAME,” attorney's docket number 30794.288-US-P1 (2009-154-1);

which application is incorporated by reference herein.

This application is related to the following co-pending and commonly-assigned U.S. patent applications:

U.S. Utility patent application Ser. No. 11/921,396, filed on Nov. 30, 2007, by Kenji Fujito, Tadao Hashimoto and Shuji Nakamura, entitled “METHOD FOR GROWING GROUP-III NITRIDE CRYSTALS IN SUPERCRITICAL AMMONIA USING AN AUTOCLAVE,” attorneys docket number 30794.129-US-WO (2005-339-2), which application claims the benefit under 35 U.S.C. Section 365(c) of PCT Utility Patent Application Serial No. US2005/024239, filed on Jul. 8, 2005, by Kenji Fujito, Tadao Hashimoto and Shuji Nakamura, entitled “METHOD FOR GROWING GROUP III-NITRIDE CRYSTALS IN SUPERCRITICAL AMMONIA USING AN AUTOCLAVE,” attorneys' docket number 30794.129-WO-01 (2005-339-1);

U.S. Utility patent application Ser. No. 11/784,339, filed on Apr. 6, 2007, by Tadao Hashimoto, Makoto Saito, and Shuji Nakamura, entitled “METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-U1 (2006-204), which application claims the benefit under 35 U.S.C. Section 119(e) of U.S. Provisional Patent Application Serial No. 60/790,310, filed on Apr. 7, 2006, by Tadao Hashimoto, Makoto Saito, and Shuji Nakamura, entitled “A METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-P1 (2006-204);

U.S. Utility patent application Ser. No. 11/765,629, filed on Jun. 20, 2007, by Tadao Hashimoto, Hitoshi Sato and Shuji Nakamura, entitled “OPTO-ELECTRONIC AND ELECTRONIC DEVICES USING N-FACE OR M-PLANE GaN SUBSTRATE PREPARED WITH AMMONOTHERMAL GROWTH,” attorneys' docket number 30794.184-US-U1 (2006-666), which application claims the benefit under 35 U.S.C. Section 119(e) of U.S. Provisional Application Ser. No. 60/815,507, filed on Jun. 21, 2006, by Tadao Hashimoto, Hitoshi Sato, and Shuji Nakamura, entitled “OPTO-ELECTRONIC AND ELECTRONIC DEVICES USING N-FACE GaN SUBSTRATE PREPARED WITH AMMONOTHERMAL GROWTH,” attorneys' docket number 30794.184-US-P1 (2006-666);

U.S. Utility patent Ser. No. 12/234,244, filed on Sep. 19, 2008, by Tadao Hashimoto and Shuji Nakamura, entitled “GALLIUM NITRIDE BULK CRYSTALS AND THEIR GROWTH METHOD,” attorneys' docket number 30794.244-US-U1 (2007-809), which application claims the benefit under 35 U.S.C. Section 119(e) of U.S. Provisional Patent Application Ser. No. 60/973,662, filed on Sep. 19, 2007, by Tadao Hashimoto and Shuji Nakamura, entitled “GALLIUM NITRIDE BULK CRYSTALS AND THEIR GROWTH METHOD,” attorneys' docket number 30794.244-US-P1 (2007-809-1);

U.S. Utility patent application Ser. No. 11/977,661, filed on Oct. 25, 2007, by Tadao Hashimoto, entitled “METHOD FOR GROWING GROUP III-NITRIDE CRYSTALS IN A MIXTURE OF SUPERCRITICAL AMMONIA AND NITROGEN, AND GROUP III-NITRIDE CRYSTALS GROWN THEREBY,” attorneys' docket number 30794.253-US-U1 (2007-774-2), which application claims the benefit under 35 U.S.C. Section 119(e) of U.S. Provisional Application Ser. No. 60/854,567, filed on Oct. 25, 2006, by Tadao Hashimoto, entitled “METHOD FOR GROWING GROUP-III NITRIDE CRYSTALS IN MIXTURE OF SUPERCRITICAL AMMONIA AND NITROGEN AND GROUP-III NITRIDE CRYSTALS,” attorneys' docket number 30794.253-US-P1 (2007-774);

P.C.T. International Patent Application Serial No. PCT/US09/______, filed on same date herewith, by Derrick S. Kamber, Siddha Pimputkar, Makoto Saito, Steven P. DenBaars, James S. Speck and Shuji Nakamura, entitled “GROUP-III NITRIDE MONOCRYSTAL WITH IMPROVED PURITY AND METHOD OF PRODUCING THE SAME,” attorneys' docket number 30794.295-WO-U1 (2009-282-2), which application claims the benefit under 35 U.S.C. Section 119(e) of U.S. Provisional Application Ser. No. 61/112,555, filed on Nov. 7, 2008, by Derrick S. Kamber, Siddha Pimputkar, Makoto Saito, Steven P. DenBaars, James S. Speck and Shuji Nakamura, entitled “GROUP-III NITRIDE MONOCRYSTAL WITH IMPROVED PURITY AND METHOD OF PRODUCING THE SAME,” attorney's docket number 30794.295-US-P1 (2009-282-1);

P.C.T. International Patent Application Serial No. PCT/US09/______, filed on same date herewith, by Siddha Pimputkar, Derrick S. Kamber, James S. Speck and Shuji Nakamura, entitled “REACTOR DESIGNS FOR USE IN AMMONOTHERMAL GROWTH OF GROUP-III NITRIDE CRYSTALS,” attorneys' docket number 30794.296-WO-U1 (2009-283/285-2), which application claims the benefit under 35 U.S.C. Section 119(e) of U.S. Provisional Application Ser. No. 61/112,560, filed on Nov. 7, 2008, by Siddha Pimputkar, Derrick S. Kamber, James S. Speck and Shuji Nakamura, entitled “REACTOR DESIGNS FOR USE IN AMMONOTHERMAL GROWTH OF GROUP-III NITRIDE CRYSTALS,” attorney's docket number 30794.296-US-P1 (2009-283/285-1);

P.C.T. International Patent Application Serial No. PCT/US09/______, filed on same date herewith, by Siddha Pimputkar, Derrick S. Kamber, James S. Speck and Shuji Nakamura, entitled “NOVEL VESSEL DESIGNS AND RELATIVE PLACEMENTS OF THE SOURCE MATERIAL AND SEED CRYSTALS WITH RESPECT TO THE VESSEL FOR THE AMMONOTHERMAL GROWTH OF GROUP-III NITRIDE CRYSTALS,” attorneys' docket number 30794.297-WO-U1 (2009-284-2), which application claims the benefit under 35 U.S.C. Section 119(e) of U.S. Provisional Application Ser. No. 61/112,552, filed on Nov. 7, 2008, by Siddha Pimputkar, Derrick S. Kamber, James S. Speck and Shuji Nakamura, entitled “NOVEL VESSEL DESIGNS AND RELATIVE PLACEMENTS OF THE SOURCE MATERIAL AND SEED CRYSTALS WITH RESPECT TO THE VESSEL FOR THE AMMONOTHERMAL GROWTH OF GROUP-III NITRIDE CRYSTALS,” attorney's docket number 30794.297-US-P1 (2009-284-1);

P.C.T. International Patent Application Serial No. PCT/US09/______, filed on same date herewith, by Siddha Pimputkar, Derrick S. Kamber, James S. Speck and Shuji Nakamura, entitled “ADDITION OF HYDROGEN AND/OR NITROGEN CONTAINING COMPOUNDS TO THE NITROGEN-CONTAINING SOLVENT USED DURING THE AMMONOTHERMAL GROWTH OF GROUP-III NITRIDE CRYSTALS,” attorneys' docket number 30794.298-WO-U1 (2009-286-2), which application claims the benefit under 35 U.S.C. Section 119(e) of U.S. Provisional Application Ser. No. 61/112,558, filed on Nov. 7, 2008, by Siddha Pimputkar, Derrick S. Kamber, James S. Speck and Shuji Nakamura, entitled “ADDITION OF HYDROGEN AND/OR NITROGEN CONTAINING COMPOUNDS TO THE NITROGEN-CONTAINING SOLVENT USED DURING THE AMMONOTHERMAL GROWTH OF GROUP-III NITRIDE CRYSTALS”, attorney's docket number 30794.298-US-P1 (2009-286-1);

P.C.T. International Patent Application Serial No. PCT/US09/______, filed on same date herewith, by Siddha Pimputkar, Derrick S. Kamber, James S. Speck and Shuji Nakamura, entitled “CONTROLLING RELATIVE GROWTH RATES OF DIFFERENT EXPOSED CRYSTALLOGRAPHIC FACETS OF A GROUP-III NITRIDE CRYSTAL DURING THE AMMONOTHERMAL GROWTH OF A GROUP-III NITRIDE CRYSTAL,” attorneys' docket number 30794.299-WO-U1 (2009-287-2), which application claims the benefit under 35 U.S.C. Section 119(e) of U.S. Provisional Application Ser. No. 61/112,545, filed on Nov. 7, 2008, by Siddha Pimputkar, Derrick S. Kamber, James S. Speck and Shuji Nakamura, entitled “CONTROLLING RELATIVE GROWTH RATES OF DIFFERENT EXPOSED CRYSTALLOGRAPHIC FACETS OF A GROUP-III NITRIDE CRYSTAL DURING THE AMMONOTHERMAL GROWTH OF A GROUP-III NITRIDE CRYSTAL,” attorney's docket number 30794.299-US-P1 (2009-287-1), and

P.C.T. International Patent Application Serial No. PCT/US09/______, filed on same date herewith, by Siddha Pimputkar, Derrick S. Kamber, James S. Speck and Shuji Nakamura, entitled “USING BORON-CONTAINING COMPOUNDS, GASSES AND FLUIDS DURING AMMONOTHERMAL GROWTH OF GROUP-III NITRIDE CRYSTALS,” attorneys' docket number 30794.300-WO-U1 (2009-288-2), which application claims the benefit under 35 U.S.C. Section 119(e) of U.S. Provisional Application Ser. No. 61/112,550, filed on Nov. 7, 2008, by Siddha Pimputkar, Derrick S. Kamber, James S. Speck and Shuji Nakamura, entitled “USING BORON-CONTAINING COMPOUNDS, GASSES AND FLUIDS DURING AMMONOTHERMAL GROWTH OF GROUP-III NITRIDE CRYSTALS,” attorney's docket number 30794.300-US-P1 (2009-288-1);

all of which applications are incorporated by reference herein.

### BACKGROUND OF THE INVENTION

1. Field of the Invention

The present invention relates to growth of group-III nitride crystals, more particularly to providing a high crystal quality group-III nitride crystal grown on an etched-back seed crystal in a supercritical nitrogen-containing solvent, and a method to improve the crystal quality of a group-III nitride crystal grown on a seed crystal in a supercritical nitrogen-containing solvent.

2. Description of the Related Art

(Note: This application references a number of different publications as indicated throughout the specification by one or more reference numbers within brackets, e.g., [Ref x]. A list of these different publications ordered according to these reference numbers can be found below in the section entitled “References.” Each of these publications is incorporated by reference herein.)

The usefulness of gallium nitride (GaN) and its alloys incorporating aluminum, boron, and indium (AlₓB_{y}In_{z}Ga_{1-x-y-z})N, in which 0≦x≦1, 0≦y≦1, 0≦z≦1, and 0≦x+y+z≦1 has been well established for fabrication of visible and ultraviolet optoelectronic devices, and high-power electronic devices. These devices are typically grown epitaxially using growth techniques such as molecular beam epitaxy (MBE), metalorganic chemical vapor deposition (MOCVD), and hydride vapor phase epitaxy (HVPE).

GaN and its alloys are the most stable in the hexagonal würtzite crystal structure, in which the structure is described by two (or three) equivalent basal plane axes that are rotated 120° with respect to each other (the a-axis), all of which are perpendicular to a unique c-axis. Group-III and nitrogen atoms occupy alternating c-planes along the crystal's c-axis. The symmetry elements included in the würtzite structure dictate that group-III nitrides possess a bulk spontaneous polarization along this c-axis, and the würtzite structure also exhibits piezoelectric polarization.

Current nitride technology for electronic and optoelectronic devices typically employs nitride films grown along the polar c-direction. However, some conventional c-plane quantum well structures in group-III nitride based optoelectronic devices suffer from the undesirable quantum-confined Stark effect (QCSE), due to the existence of strong piezoelectric and spontaneous polarizations. The strong built-in electric fields along the c-direction cause spatial separation of electrons and holes that in turn give rise to restricted carrier recombination efficiency, reduced oscillator strength, and red-shifted emission.

One approach for eliminating or reducing the spontaneous and piezoelectric polarization effects in GaN optoelectronic devices is to grow the devices on non-polar or semi-polar planes of the crystal. Recently, several reports have been published which confirmed the benefit of the non-polar and semi-polar devices [Refs. 1 and 2]. Most of them indicate that a high-quality substrate is essential for fabrication of these devices. Historically, numerous foreign substrates, such as silicon carbide (SiC), spinel (MgAl₂O₄), sapphire (Al₂O₃), etc., have been used to fabricate devices; however, the device quality has been poor due to the high defect density caused by heteroepitaxial growth of the devices on the foreign substrates with different structural properties.

While the semi-polar and non-polar directions may have substantial benefits for certain optoelectronic devices, such as Light Emitting Diodes (LEDs) and lasers, due to the polarization lying in or at an angle to the exposed surface, polar devices, where the polarization is perpendicular to the exposed surface, are equally important as this polarization effect may be used or made an integral part of the design of more sophisticated transistors and other electronic device structures.

Additionally, by utilizing semi-polar or non-polar directions during the epitaxial growth of optoelectronic and electronic devices using a growth technique such as MBE, MOCVD, or HVPE, it is possible to obtain a greater control over the degree to which desirable or undesirable elements are incorporated into the growing layers [Ref 7]. This can be used advantageously, by selecting a favorable crystallographic plane during growth which allows for significant incorporation of desired elements, for example, Indium during the growth of InGaN, allowing one to obtain certain physical properties for optoelectronic devices which can only be created, if at all, with great difficulty while growing in the polar c-direction. Further, it is possible by selecting semi-polar or non-polar growth directions to reduce incorporation of undesired elements during growth, such as oxygen and carbon, thereby creating devices of superior quality and performance.

Accordingly, high quality and high cost-performance bulk monocrystalline GaN is needed so that GaN substrates can be made for any desired crystallographic orientation, including non-polar, semi-polar and polar. This is a necessary and important step for homo-epitaxial growth and industrialization of all group-III nitride based devices. Presently, non-polar and semi-polar GaN substrates are often produced from c-plane oriented GaN boules grown by HVPE. This approach, however, suffers from limitations in substrate wafer size and inherently high production costs.

Currently, there are a variety of alternative methods being pursued for the growth of GaN single crystal substrates. In most approaches, the method involves an open or closed system with two different environments and a transport medium. One environment typically is rich in gallium and nitrogen atoms and can be thought of as a source of GaN material. The other environment often contains seed crystals and can be thought of as a sink for the GaN material. The transport medium transports the gallium and nitrogen from the source region to the seed crystals upon which these two elements then crystallize and form over time a large single crystal of GaN. In some cases, the transport medium provides the nitrogen source for GaN growth.

The various methods being pursued mostly use a fluid to transport the group-III elements and nitrogen to the seed crystals. This fluid can, for example, be in the form of a liquid alkali metal, such as sodium, as used in the sodium flux method or a supercritical fluid, such as ammonia, as used in the ammonothermal method. A supercritical fluid is essentially a state of matter wherein a liquid or gas is heated to a high enough temperature and compressed to yield a high enough pressure where the liquid and gaseous state of the elements or compounds are visually and thermodynamically indistinguishable. This new fluid state has interesting and different properties than the individual gas or liquid states possess, such as improved mass transport abilities and increased solubility of certain elements and compounds, such as GaN, within the supercritical fluid, such as ammonia.

Depending on the transport medium used, it is possible to control the solubility of elements and compounds, such as GaN, in the medium by changing parameters such as the temperature, pressure, and/or density of the fluid. Depending on the fluid and elements/compounds involved in the process, an increase in temperature can either increase or decrease the solubility of the material and similarly an increase in pressure can either increase or decrease the solubility of the material. Given this observation, it is possible to use these solubility trends advantageously by holding the source environment, which contains the gallium source, at a certain temperature and pressure and the seed crystal at a different temperature and/or pressure to facilitate dissolution of source material in one zone and preferential growth on a seed crystal in a different zone, preferably the zone containing the seed crystal.

Since in most cases the temperatures and pressures involved for the system are different than ambient conditions, it is necessary to subject the seed crystals and source material to transient conditions. These transient conditions may, for example, present themselves as a heating or cooling period, during which, for example, undesirable spontaneous growth of material on the seed crystals may occur, with this material often possessing inferior crystal quality. Not only is this spontaneously grown material on the surface of poor quality, but it may also be crystallographically misoriented with respect to the underlying crystallographic orientation of the seed crystal. This may lead to the formation of multiple crystal domains, since growth will now occur not only on the seed crystal, but also on the spontaneously grown material, which could possess a slight misorientation with respect to the seed crystal. When these two growth fronts meet, dislocations and grain boundaries are formed, causing a deterioration in crystal quality. Consequently, this undesired material may lead to an overall reduction in crystal quality of the grown single crystal after growth. This has been seen in our experiments, most notably when growth along the c-direction occurred. The resulting increase in the full width at half-maximum (FWHM) value for the omega rocking curve for the (0 0 0 2) plane, or c-plane, was from 413 arcsec to 2771 arcsec. Furthermore, the increase in FWHM values for the omega rocking curve for the (1 0-1 2) plane was from 87 arcsec to 618 arcsec. Both of these increases in the value of FWHM are at least partially due to the creation of multiple crystal domains within the GaN crystal.

Furthermore, other undesirable material on the surfaces of the seed crystal may also lead to a reduction in crystal quality of the grown single crystal, including oxide layers or contaminants on the surfaces of the seed crystals. Removal of any undesired material on the surface of the seeds, a process which may be referred to as etch-back, prior to growing on the seed crystals may be beneficial, as this may cause the newly grown single crystal on the seed crystal to be of a higher crystal quality. Using this higher crystal quality crystal as a substrate may then directly translate into improved performance and electrical properties for any epitaxially grown optoelectronic or electronic device.

To the best of our knowledge, crystal quality improvement upon etch-back of the seed crystal has not been previously observed or reported. Various groups have used methods that caused dissolution of the surface intentionally or unintentionally prior to growth, but all of these reports depicted a worsening of the crystal quality after seed crystal dissolution. For example, M. Callahan's group reports an increase in dislocation density on the surface after etching back [Refs. 3 and 4] and T. Hashimoto [Refs. 5 and 6] describes dissolution being a possible cause of voids in his crystals.

The present invention provides a method to improve the crystal quality of a group-III nitride crystal grown on a seed crystal in a supercritical nitrogen-containing solvent by removing any undesired material from the surfaces of the seed crystal. The present invention also provides a high crystal quality group-III nitride crystal grown on an etched-back seed crystal in a supercritical nitrogen-containing solvent. Furthermore, the present invention also provides a method to etch-back the source material for growth of a group-III nitride crystal in a supercritical nitrogen-containing solvent.

### SUMMARY OF THE INVENTION

To overcome the limitations in the prior art described above, and to overcome other limitations that will become apparent upon reading and understanding the present invention, the present invention discloses a method to improve the crystal quality of a group-III nitride crystal grown on a seed crystal in a supercritical nitrogen-containing solvent by removing any undesired material from the surfaces of the seed crystal. The present invention also provides a high quality group-III nitride crystal grown on an etched-back seed crystal in a supercritical nitrogen-containing solvent. Furthermore, the present invention also provides a method to etch-back the source material for growth of a group-III nitride crystal in a supercritical nitrogen-containing solvent.

The present invention has found that by performing an etch-back, where material is intentionally removed from the surfaces of the seed crystal prior to growing new material on the seed crystal, the crystal quality of the grown material is comparable to the crystal quality of the seed crystal itself. The present invention was able to establish conditions and methods that prevent deterioration of the crystal quality of the newly grown material on etched-back seed crystals. Furthermore, the conditions and methods produce a clear improvement in crystal quality of the newly grown crystal on the seed crystal as compared to previously grown material. This method involves loading ammonia, GaN source material, seed crystals, such as GaN substrates grown by HVPE methods, and mineralizers, which improve the solubility of GaN into the solvent, into a vessel. This vessel is then sealed and the region in which the source material is found is maintained at a temperature between 0° C. and 1000° C., and similarly the region in which the seed crystals can be found is maintained at a temperature between 0° C. and 1000° C., but a temperature difference between the source material zone and the seed crystals zone is maintained. This temperature gradient between source materials zone and seed crystals zone may be between 1° C. and 1000° C. The temperatures for the two different zones are chosen so that the solubility of GaN into solution is higher in the seed crystals zone and lower in the solubility zone. Furthermore, the temperatures of the regions and amount of ammonia filled into the vessel are chosen as to preferentially create a supercritical state for the nitrogen-containing solvent. These etch-back conditions may be applied during one or more times, including times when the vessel is being heated to higher temperature(s) or when the vessel has reached the higher temperature(s)

After a certain period of time, which may be, for example, any period between 1 minute and 10 days, although this time period should by no means be considered limiting and the etch-back could occur for shorter or longer times, the etch-back conditions are discontinued and conditions for growth are imposed on the system. Generally speaking, this involves a reversal in the temperature gradient. By changing the temperature gradient the solubility of GaN into solution is now higher in the source material zone and lower in the seed crystals zone, typically resulting in film growth.

When analyzing GaN crystals grown on etched-back seeds, it was seen that the FWHM for the (0 0 0 2) planes, or c-planes, of hexagonal würtzite GaN was between 40 arcsec and 413 arcsec, depending on which particular facet was analyzed on the grown crystal. These values are comparable to the crystal quality of the seed crystal itself. When performing this X-ray analysis on crystals grown without etch-back prior to growth but under identical growth conditions, the FWHM values for the (0 0 0 2) planes, or c-planes, of hexagonal würtzite GaN were between 90 arcsec and 2771 arcsec.

Overall, an improvement in crystal quality for every facet of the GaN crystal was observed when performing etch-back on the seed crystal prior to growth. The present invention, therefore, describes a high crystal quality group-III nitride crystal, such as GaN, grown on an etched-back seed crystal in a supercritical nitrogen-containing solvent, such as ammonia, and further the method used to achieve this superior crystal quality.

### BRIEF DESCRIPTION OF THE DRAWINGS

Referring now to the drawings in which like reference numbers represent corresponding parts throughout:

FIG. 1 is a schematic of a high-pressure vessel according to an embodiment of the present invention.

FIG. 2 is a flowchart illustrating the method according to an embodiment of the present invention.

FIG. 3a is a graph that illustrates the XRD omega rocking curve for 0002 Bragg plane reflections of the (0001) Ga-face, and FIG. 3b is a graph that illustrates the XRD omega rocking curve for 10-12 Bragg plane reflections of the (0001) Ga-face.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention describes a high crystal quality group-III nitride crystal grown on an etched-back seed crystal in a supercritical nitrogen-containing solvent, and further a method to improve the crystal quality of a group-III nitride crystal grown on a seed crystal in a supercritical nitrogen-containing solvent by removing any undesired material from the surfaces of the seed crystal. Additionally, the present invention also provides a method to etch-back the source material for growth of a group-III nitride crystal in a supercritical nitrogen-containing solvent.

It has been observed that when growing group-III nitride crystals on a seed crystal in a supercritical nitrogen-containing solvent that the crystal quality of the grown layer is often poorer than that of the seed crystal. This is an undesired effect and the present invention has found a method to eliminate this occurrence. Accordingly, a method for growing high crystal quality group-III nitride crystals in supercritical ammonia has been proposed and demonstrated. This method may be implemented to produce, for example, bow-free GaN substrates containing low structural defect densities in a cost-effective manner.

Definitions of Terms

In this application, various terms are used that may not be common across researchers and groups, and therefore, these terms will be briefly defined below. The following statements are only meant to be for illustrative purposes and further interpretations and expansions to the following statements are possible.

Mineralizer: An element or compound added to the supercritical nitrogen-containing solvent, such as ammonia or one of its derivatives, to increase solubility of a material into the solvent. The addition of this material may cause the ammonia to remain neutral or become either acidic or basic. Mineralizers that may cause the ammonia fluid to become basic include, but are not limited to, alkaline metals such as lithium, sodium, potassium, rubidium, cesium and francium and alkali earth metals such as beryllium, magnesium, calcium, strontium, barium and radium. Mineralizers that may cause the ammonia fluid to become acidic include, but are not limited to, compounds containing the halogens such as fluorine, chlorine, bromine, iodine and astatine. A mixture of these mineralizers may make the mixture neutral again.

Source Material: Material that is consumed in the process of growing on a seed crystal. The form of the source material may be, for example, in the form of a powder, liquid, or solid. The composition of the source material is such that it contains at least one group III element. The chemical composition of the material may be in its pure elemental form, or in any possible chemical compound, for example, in the form of an amide or azide. Further, while the source material contains a group III element, it can also intentionally contain other elements or compounds, which may be used as, for example, doping agents or for other purposes. The source material may be GaN.

Seed crystal: A monocrystalline or polycrystalline material upon which the group-III nitride crystal is grown. It may possess any shape, size or form, and may consist of any material with any number of crystallographic facets of the crystal exposed. It is preferable that the seed crystal is a pure single crystal with the smallest number of point, line and volume defects. The seed crystal may or may not have the same composition and/or crystal structure as the group-III nitride crystal that is grown upon it.

Technical Description

The present invention provides a group-III nitride crystal grown on an etched-back seed crystal. It further comprises a method for improving the crystal quality, among other things, of a group-III nitride crystal grown in a supercritical nitrogen-containing solvent. This invention achieves this by removing material from the surface of the seed crystal prior to growing a group-III nitride crystal. Additional material on the surface, that is almost always present due to the processing steps required to setup the environment to grow this group-III nitride crystal and due to natural processes, such as oxide formation, may reduce the quality of the seed crystal resulting in inferior quality of the grown group-III nitride crystal. It is crucial that this additional material is removed, allowing the group-III nitride crystal to crystallize and grow on a clean, high-quality surface of the seed crystal. Furthermore, the present invention also provides a method to etch-back the source material for growth of a group-III nitride crystal in a supercritical nitrogen-containing solvent.

The method of this invention may require various components to successfully perform and to create the material of this invention. The components needed may include, but are not limited to, a vessel, a supercritical nitrogen-containing fluid, source material, and at least one seed crystal. Optional components that may be used include, but are not limited to, additional elements and compounds added to the supercritical nitrogen-containing fluid, such as mineralizers, devices that separate space into different regions, such as baffles, heaters, or at least one pressure valve including appropriate tubing and connectors.

The method put forth in this invention envisions that any group-III nitride crystal, and the associated alloys, can be grown on a seed crystal. This seed crystal can be made of any material, preferably though a material that is stable in a supercritical nitrogen-containing fluid and is a single crystal. Additionally, it is advantageous to have a seed crystal that possesses a crystal structure that, when grown upon, allows for the growth of the desired crystal structure of the group-III nitride crystal. In order to achieve this, it is convenient to use a seed crystal that possesses the same or similar crystal structure as the desired group-III nitride crystal structure, and/or has a surface (upon which the group-III nitride is grown) that possesses a similar pattern and spacing of atoms to those of any particular crystallographic plane of the desired group-III nitride crystal in its desired crystal structure. Also, it is convenient to use a seed crystal that is perfect, or if not available as a perfect single crystal, at least one that has the lowest possible number of defects, such as dislocations. The density of dislocations in the seed crystal should ideally be 10⁶/cm² or less.

The seed crystal, therefore, should ideally be a crystal that is very similar in structure, at the surface, to the desired group-III nitride crystal, yet may be different in composition. Possible examples of seed crystals include, but are not limited to, group-III nitride alloys (AlₓB_{y}In_{z}Ga_{1-x-y-z})N, in which 0≦x≦1, 0≦y≦1, 0≦z≦1, and 0≦x+y+z≦1 with or without the addition of other elements, sapphire, spinel, lithium aluminate, gallium arsenide, silicon, lithium gallate, lithium aluminum gallate, diamond, magnesium oxide, molybdenum, tungsten, tungsten carbide, zinc oxide, silicon carbide, tantalum nitride, niobium nitride, silver diboride, gold diboride, hafnium diboride, molybdenum carbide, hafnium, zirconium.

Possible examples of crystal structures for the seed crystal include, but are not limited to, tetragonal crystal structures, hexagonal crystal structures such as the würtzite crystal structure or the hexagonal closed packed crystal structures, and cubic crystal structures such as the zincblende crystal structure, or body-centered cubic crystal structures having a lattice constant of 2.8 to 3.6 Angstroms (Å) on the aₒ axis and being cut perpendicular to the [111] direction.

While it is possible to use seed crystals of different composition and structure than the desired group-III nitride crystal, it is preferable to use a seed crystal that is of the same composition and crystal structure. Such a seed crystal would therefore, for example, be GaN if the desired group-III nitride crystal to be grown was GaN. The method used to produce the desired group-III nitride seed crystal may be any growth method, including but not limited to, ammonothermal methods, HVPE methods, MOCVD methods, MBE methods, PVT (Physical Vapor Transport) methods, HPSG (High-Pressure Solution Growth) methods, and flux methods.

In addition to having a seed crystal with similar structural properties and composition to the growth layer, it is preferable to have a seed crystal that is perfect and pure. The concentration of undesired elements or compounds in the seed crystal itself should be kept at a minimum. The density of dislocations on the surface should preferably be below 10⁶/cm².

The source material used in the present invention provides material which will be used for the growth of the group-III nitride. There is no restriction on the chemical composition(s), form(s), or phase(s) of the source material(s), yet it is necessary that it contains at least one group-III element (B, Al, Ga, In, Tl). It is possible to have more than one group-III element in the source material. It is further possible that the source material is a mixture of materials possessing different chemical compositions, forms, and/or phases. For example, the source material could include simultaneously both polycrystalline GaN and metallic Ga, or it could include polycrystalline AlGaN and gallium amide.

Possible forms and phases of the source material include, but are not limited to, solid chunks of material, powder, liquid and/or gaseous material.

Possible chemical compositions of the source material include, but are not limited to, compounds of a group-III element with other group-III elements (B, Al, Ga, In, Tl), group-IV elements (C, Si, Ge, Sn, Pb), group-V elements (N, P, As, Sb, Bi), group-VI elements (O, S, Se, Te, Po), group-VII elements (F, Cl, Br, I, At), and/or hydrogen. Preferable compounds include, but are not limited to, nitrides, hydrides, amides, imides, amido-imides, and azides. For example, if Ga is one of the group-III elements in the source material, it can be provided as a nitride (GaN), as a hydride (such as GaH₃), as an amide (such as Ga(NH₂)₃), as an imide (such as Ga₂(NH)₃), as an amido-imide (such as Ga(NH)NH₂), and as an azide (such as GaN₃).

Additionally, possible chemical compositions of the source material include, but are not limited to, their pure elemental form, inter-metallic compounds of one or more group-III elements with other group-III elements or other metals, for example, group-I elements (Li, Na, K, Rb, Cs), group-II elements (Be, Mg, Ca, Sr, Ba, Ra) and/or transition metals. For example, if Ga is one of the group-III elements in the source material, it can be provided as metallic gallium.

If additional elements are to be added to the group-III nitride crystal during growth, it is possible to add/mix these elements to/with the source material containing group-III element(s) in the form of a compound, in their pure elemental form, or have them in the same compound as at least one of the group-III element(s). Additional elements that may be added to the source material may include, be are not limited to, C, Si, Ge, Sn, Pb, O, and S as they may act as donors, Be, Mg, Ca, Sr, Zn, Cd, and Hg as they may act as acceptors, and Mn, and Cr as they may act as magnetic-type dopants. Preferably, if the group-III nitride crystal should be donor-type doped one would use Si or O, for acceptor-type doping Mg or Zn, and for magnetic-type doping Mn or Cr. Any other elements or compounds that may be added to dope the group-III nitride crystal are also consistent with the present invention.

The method put forth in this invention envisions that the group-III nitride crystal is grown in supercritical nitrogen-containing fluid. This fluid may be added to the system already in the supercritical state, or may be added as a regular gas, liquid and/or solid, and subsequently heated and/or pressurized to conditions under which it is a supercritical fluid.

The supercritical nitrogen-containing fluid may provide the nitrogen element in its elemental form N₂, or in the form of a compound, such as ammonia (NH₃) or one of its derivatives such as hydrazine (N₂H₄), or in any mixture of various nitrogen-containing compounds and elemental forms. The preferable supercritical nitrogen-containing fluid is composed largely of ammonia (NH₃).

The supercritical nitrogen-containing fluid may intentionally, or unintentionally, additionally include elements or compounds that do not contain nitrogen as an element, such as, H₂, noble gases (He, Ne, Ar, Kr, Xe, Rn), halogen gases such as F₂, Cl₂, Br₂, I₂, At₂, and/or various compounds of different elements from the periodic table of elements such as H₂O.

The method put forth in this invention envisions that any group-III nitride crystal is grown within a vessel. This vessel may be composed of one or more different types of materials and may be of any size and shape, though a cylindrical or spherical shape is preferable. It is also preferable that this vessel is designed to safely withstand pressures between 0 and 30000 atmospheres and temperatures between −200° C. and 1000° C. Optionally, this vessel could also have the ability to form a closed system, with one or more valves allowing transport of material in and out of the vessel at any time during the operation. Given the high pressures and temperatures involved in the process, it is convenient to use super alloys, such as a Ni—Cr super alloys, that can safely withstand high pressures and temperatures. Furthermore, it is possible to line the vessel with a second material that is of higher purity and/or has other advantageous properties. Other vessel optional are also possible and within the scope of this invention.

Given the four basic components needed for this invention, there are a few additional, optional components that may be utilized to optimize the method of this invention. Some of the optional components include chemicals that enhance the solubility of any of the source materials into the supercritical nitrogen-containing fluid, called a mineralizer, and devices that restrict and/or control the flow of fluid between different zones within the vessel, such as baffles.

The main purpose of the mineralizer is to enhance the solubility of the source material into the solvent. The reason that this is sometimes necessary is that, for example, group-III elements have a low solubility (around 1%) in a pure nitrogen-containing solvent such as ammonia, where the solubility may be defined as the ratio of the amount of group-III element in solution over the amount of solvent. The resulting expression is dimensionless and can be expressed as (moles of group-III elements)/(moles of nitrogen-containing solvent). One percent solubility would therefore mean, for every 100 moles of solvent, for example ammonia, there is one mole of group-III element. By the addition of a mineralizer, the solubility of the group-III element into the solvent increases above 1% to around 1%-30%. This is beneficial as this allows for a higher density of group-III material in the solvent, thereby, among other things, increasing the probability for faster growth of the group-III nitride crystal. The mineralizer material can be added in any form, phase or composition anywhere within the vessel at any time during or before the intended etch-back and/or growth period(s).

The material that acts as a mineralizer may comprise any element or compound made from any number of elements from the periodic table of elements. One option is to have elements or compounds which contain elements from the group-I elements (alkali metals: Li, Na, K, Rb, Cs, Fr) and/or group-II elements (alkaline earth metals: Be, Mg, Ca, Sr, Ba, Ra) added. Particularly, the use of the elements Li, Na, and K as mineralizers, provided in their elemental form and/or in any compound which is rich in N, and/or H, such as sodium azide (NaN₃) and/or sodium amide (NaNH₂) are useful when employing basic chemistry. Mineralizers may be added that cause the ammonia fluid to become acidic may be added and include, but are not limited to, compounds containing the halogens such as fluorine, chlorine, bromine, iodine and astatine. Further, other elements or compounds which contain at least one element from group-IV (C, Si, Ge, Sn, Pb), group-V (N, P, As, Sb, Bi), and group-VI (O, S, Se, Te, Po) to further improve the characteristics of the solubility of the group-III element. The present invention may include the addition of any mineralizer or combination of mineralizers.

Depending on the material used as a mineralizer, it may cause the nitrogen-containing supercritical fluid, such as ammonia, to become acidic, neutral or basic. Examples of materials that cause ammonia to become acidic include, but are not limited to, NH₄Cl and/or NH₄Br, materials that causes ammonia to become basic include, but are not limited to, NaNH₂ and/or NaN₃.

Another optional component that may be used with the method put forth in this invention is a device that controls and/or restricts fluid motion between different regions of the vessel. The purpose of this device is to separate two or more regions allowing for gradients to be established between the regions. The gradient created across the device may include, but is not limited to, temperature gradients, density gradients, and pressure gradients. This device may be either an active device, such as a fan, or passive device, such as a valve, membrane, or mesh, yet it is preferable to use a passive device, such as a plate with holes in it, typically referred to as a baffle. This device may take any shape or form, yet it is preferable to use one or more metal plates that conform to the shape of the vessel being used. There is no restriction on the number of devices that may be used, and how many components are required to create a single device.

It is preferable, though, when using a single cylindrical vessel to use only one such device and place it in such a fashion as to separate the vessel into at least two separate zones. The device used in this case, may comprise one or more circular (or disc shaped) plates of any thickness that have various shapes cut out to allow for fluid to flow through the plates and between zones. The plates may have any separation between each other. When used in this configuration it is sometimes convenient to refer to this device as a baffle plate or baffle plates.

Given the above mentioned required and optional components of the method put forth in the invention, it is possible to combine them in any desired fashion, with the only requirement that the source material, the seed material and the supercritical nitrogen-containing fluid is placed within the vessel and that the source material and seed material are placed within the vessel in such a fashion that they are in two identifiable regions. These two regions may be spatially separated or they may be overlapping with portions of the source material and portions of the seed material occupying the same spatial region. It may be further desirable to place the seed material and source material in such a fashion within the vessel that at least one more zone may be created within the vessel which is free of both the source material and seed material. These zones may or may not be spatially defined or separated by baffle plates or other devices, and may or may not contain any possible combination of materials and/or chemicals, including seed and/or source material.

It is preferable to use a cylindrical vessel that is made of a high strength material that can withstand pressures of 0 to 30000 atmospheres and temperatures between −200° C. and 1000° C., however this is not a requirement of the present invention, and to load the source material and seed material in such as fashion that the two regions within the vessel may be separated by the use of one or more baffle plates.

Having created an environment in which there is at least one zone containing source material and at least one other zone containing seed crystals, both of which are immersed in a supercritical nitrogen-containing fluid within a vessel, it is possible to create conditions under which the seed crystals lose material from one or more of their surfaces, a process that may be referred to as etch-back. Alternatively, conditions may be created under which the source material loses material from one or more of its surfaces, a process that may also be referred to as etch-back. The exact conditions required to allow this process to occur depend on the supercritical nitrogen-containing fluid and, if present, on the particular mineralizers. Generally, the conditions required for this etch-back to occur comprise creating a solubility difference between the seed crystals zone and the source material zone and/or creating a solubility difference between the seed crystals zone and at least one additional zone within the vessel, and/or creating a solubility difference between the source material zone and at least one additional zone within the vessel.

If etch-back of the seed crystal is desired, it is desirable to have the seed crystals immersed in a region which has a higher solubility of the group-III material in the supercritical nitrogen-containing fluid and creating a second region within the vessel which has a lower solubility of group-III material in the supercritical nitrogen-containing fluid. This second region within the vessel may be the source material zone and/or any number of additional regions or zones.

Alternatively, when etch-back of the source material is desired, it is desirable to create a solubility difference between the source material zone and either the seed material zone or any number of additional unspecified regions or zones within the vessel. It is desirable to place the source material in the higher solubility zone and create a lower solubility zone in a different spatial location within the vessel. This lower solubility zone may overlap and/or encompass the seed crystals zone containing seed crystals, or it may encompass another zone which contains nothing, or it may encompass a zone which contains other material which may allow for the nucleation and deposition of group-III nitride material or other material.

In combination with this solubility difference and the resulting mass transport of group-III elements through diffusion, it may be advantageous to create fluid motion between the various regions within the vessel. Fluid motion may be used to transport material from zones of high solubility to zones of lower solubility. This motion can be actively induced with an electromagnetic or mechanical device, such as a fan, or preferably, passively, for example, by making use of natural convection within the vessel. Natural convection within the vessel may be induced, for example, by creating a density difference across two different regions within the vessel causing fluid motion.

One example for this particular method of creating a natural convective flow within the vessel, which should not be considered limiting in any fashion, would be to fill a vessel with ammonia and heat the lower zone of a vertically positioned cylinder to a higher temperature than the upper zone. The higher temperature in the lower zone of the cylinder causes the ammonia to be of a lower density and, based on buoyancy, the fluid rises to the top of the vessel. The fluid on the top of the vessel is cooler, thereby making it of slightly higher density and causing it to drop to the bottom of the vessel, once again due to buoyancy. This unstable situation can result in steady state fluid motion, encouraged by creating a temperature gradient between the top and bottom of a vertically positioned cylindrical vessel. This fluid motion may not only be induced by a temperature gradient across two vertically aligned regions within the vessel, but also may, for example, by a pressure gradient or temperature gradient across one or more regions within the vessel, which may or may not be aligned vertically with respect to each other.

The combination of fluid motion within the vessel, natural diffusion of group-III elements and the existence of at least two regions of different solubility within the vessel causes group-III elements, among other things, to be transported from the higher solubility region to the lower solubility region. For etch-back of the seed crystals, the seed crystals are placed in the higher solubility region and at least one lower solubility region within the vessel is created. This lower solubility region may coincide with the source material zone or any other number of regions within the vessel. This may cause material to be removed from the seed crystals, thereby causing etch-back, and to be transported to the source material region and/or any other region, where, due to the lower solubility of the group-III elements in the solvent in the non-seed crystal region, the material comes out of solution due to supersaturation and precipitates out of solution onto any available object, wall, or material, such as group-III source material, within the lower solubility region or regions.

While it is possible that the group-III elements precipitate out, it is possible to configure the vessel and conditions in such a fashion that material is removed from the seed crystals and dissolved into the supercritical nitrogen-containing fluid, but does not precipitate out of solution, even in the lower solubility region where conditions may be chosen such that the amount of dissolved group-III elements is still less than the maximum solubility limit, even if this limit has been chosen in such a fashion that it is lower than that of the seed crystal region. By doing so the solution never becomes super-saturated and hence precipitation may not occur. Furthermore, conditions may be chosen such that the solution is not supersaturated in any zone, but such that etch-back is still occurring in one or more zones.

The method used to change the solubility of the supercritical nitrogen-containing fluid in the source material zone and the seed crystals zone may include, but is not limited to, changing the temperature, pressure, density, amount of dissolved mineralizer, and physical size of each region.

It has been observed that the amount of solubility of group-III elements is a function of, among other possible parameters, temperature, pressure and density. Therefore, one can change any one or more of these parameters within the respective region or zone, thereby causing a change in solubility. It is preferable to control the solubility of the group-III element in solution by changing temperature. One example of creating this solubility difference, includes, but is not limited to, heating one zone of the vessel to a higher temperature than another zone. This causes one zone to have a higher or lower solubility than the other, depending on the particular type of supercritical nitrogen-containing fluid used and which mineralizers are present.

Placing the seed crystals in the higher solubility region and creating a lower solubility region, which may contain the source material, is an integral component of the present invention for etch-back of the seed crystals. Placing the two regions in such a relationship to each other that allows for fluid motion between the two zones is advantageous but not necessary, as it might be preferable to have mass transport occur only through diffusion and not through a combination of diffusion and fluid motion.

As an example, though it should not be considered limiting in any fashion, for a basic ammonia containing supercritical fluid, it may be preferable to place the seed crystals at a lower temperature than the source material, thereby causing the group-III nitride to have a higher solubility in the seed region than in the source material region, and to have the seed crystals in the upper zone of the vessel and the source material in the lower zone (in the case of a vertically positioned vessel that is separated into an upper and lower zone as previously described). This provides a combination of the desired solubility difference between the two zones and fluid motion through natural convection. Other possibilities for the positioning of the seed crystal zone and source materials zones and their corresponding temperatures are possible. One such possibility includes creating a third zone with lower solubility within the vessel, with this third region optionally not containing source material or seed material, and therefore, the above mentioned example should by no means be considered limiting.

One deviation of the above example would be to interchange the position of the two zones, specifically the seed zone and the source zone. By having the seed crystals at the bottom in the lower temperature zone and the source material in the upper higher temperature zone, convection may not exist and the dominant transport mechanism for the group-III elements becomes diffusion. The advantage of using this configuration is that during growth, when the solubility gradient and consequently (in this particular example) the temperature gradient is reversed, convective flows would dominate. This may be advantageous and preferable, as the growth period may be of much longer duration than the etch-back period and faster growth rates may be preferred over faster etch-back rates.

As a second example, it would be possible to use an acidic nitrogen-containing supercritical fluid. It has been observed that for certain acidic supercritical fluids it may be necessary to have the seed crystals at a higher temperature than the source material in order to have the seed crystal in a higher solubility region and the source material in a lower solubility region. By having these temperature regions, it becomes advantageous, though not necessary, to place the seed crystals in the upper zone of the vertically aligned vessel, which has been separated into an upper and lower zone as previously described, and the source material in the lower zone to make use of convective flows within the vessel.

The previous descriptions have provided multiple examples of ways to etch the surfaces of seed crystals within a vessel containing a supercritical fluid, including creating solubility gradients within the vessel in order to etch the surfaces of seed crystals. The present invention simply requires that etch-back of the seed crystal occurs. This etch-back may be accomplished using a variety of vessel designs, temperature, pressure, and density profiles, and mineralizers including, acidic, basic, and neutral mineralizers that may demonstrate normal or retrograde solubility. Furthermore, conditions may be chosen within the vessel such that the supercritical fluid does not become supersaturated in any zone, but such that etch-back is still occurring in one or more zones.

The present invention may also be used to etch-back the source material within the system. As described previously, it has been observed that the amount of solubility of group-III elements is a function of, among other possible parameters, temperature, pressure and density. Therefore, one can change any one or more of these parameters within the respective region or zone, thereby causing a change in solubility. It is preferable to control the solubility of the group-III elements in solution by changing temperature. One example of creating this solubility difference, includes, but is not limited to, heating one zone of the vessel to a higher temperature than another zone. This causes one zone to have a higher or lower solubility than the other, depending on the particular type of supercritical nitrogen-containing fluid used and which mineralizer(s) are present. This behavior can be utilized to etch-back the source material used in the growth process. The source material may contain surface oxides, impurities, contaminants, and/or other undesirable features or properties that are potentially hazardous to the growing crystal. Although etch-back of the seed crystal as described previously in the present invention may help to mitigate the effects of these contaminants, direct etch-back of the source material provides another method for removing the contaminants from the source material.

The present invention may utilize solubility differences as discussed previously to preferentially etch-back the material in the source region of a vessel. The material that is etched-back may include any surface oxides, impurities, or contaminants that are present near the surfaces of the material in the high solubility region. The etch-back in the source region may also be used to remove any source material of undesirable or inferior quality that is present. Furthermore, the etch-back may be used to produce source material possessing certain desirable surfaces or facets which advantageously affect the growth of the group-III nitride crystal. Additionally, conditions may be chosen such that the solution is not supersaturated in any zone, but such that etch-back of the source material is still occurring in one or more zones. This means a solubility difference is not required according to the present invention.

Many different conditions for etch-back may be utilized to etch-back material in the source region, but, in general, it is preferable to utilize conditions that create a high solubility of the undesirable source material in the source region, and optionally a lower solubility of these undesirable materials in a different region, such as the seed region or a separate region. Additionally, it is possible to configure the vessel and conditions in such a fashion that material is removed from the source material region and dissolved into the supercritical nitrogen-containing fluid, but does not precipitate out of solution in the lower solubility region, since the conditions were chosen such that the amount of dissolved group-III elements and/or other material is still less than the maximum solubility limit in the lower solubility region. By doing so the solution never becomes super-saturated and hence precipitation may not occur. Furthermore, this etched-off material from the source region may subsequently be removed from the autoclave. This could be accomplished, for example, by removing the solvent containing the soluble materials from the vessel. This removal may be accomplished, for example, by venting the vessel after etch-back.

Etch-back of the source material may be performed before, during, and/or after the etch-back of the seed crystals and similarly the etch-back step of the seed material may be performed before, during and/or after the etch-back of the source material. Furthermore, etch-back of both the source material and the seed crystals is not required, with etch-back of only one or the other performed. Additionally, any number of etch-back steps may be performed before, during, and/or after growth occurs on the seed crystals. The etch-back step of either the source material and/or seed material may be performed any number or times with any conditions that cause etch back of the source material and/or seed material.

For both etch-back of the seed material and etch-back of the source material, the conditions under which the solubility difference between the two (or more) zones are not the same conditions obtained under ambient conditions, so there will be a transient period in which the conditions are changing. During this period, and during any period during the etch-back procedure when the conditions are changed, it may be advantageous to ensure that the desired difference in solubility exists throughout the transient period, even if it is not of the magnitude desired in the steady-state conditions. In the example mentioned above where the solubility difference was controlled by temperature gradients, which is not the only possible method and should therefore only be considered as one of many possibilities, it is possible to achieve this by first heating the zone which requires a higher temperature, and then after a certain time delay of a couple seconds, minutes or hours, yet preferably around a 0.1-20 minutes, start heating the second zone, which requires a lower temperature. By doing so, it may be possible that a solubility difference is maintained in the desired direction during the transient period.

In the present invention, there is no restriction on the number of different conditions or on the duration of these conditions. It is possible to initially maintain a solubility gradient between two or more zones under certain conditions and then change the character and/or magnitude of the solubility gradient, while still maintaining the direction of solubility gradient, yet changing other parameters and the conditions themselves. An example of this would be to maintain an initial temperature gradient between two or more zones, and then change the magnitude of the temperature gradient and/or the values of the temperatures of the different zones. This my be advantageous to do if one desires to initially have, for example, a fast etch-back rate, and then at a later point in time prior to growth a slower etch-back rate. This may be achieved by initially having a large solubility gradient and/or a faster flow of fluids within the vessel and then at a later time a smaller solubility gradient and/or a slower moving fluid within the vessel. Furthermore, the solubility gradient may be established at any point during the process, including before, during or after the transient period. Additionally, the solubility gradient need not exist for all periods of time prior to growth, and could be created immediately before initiation of the desired growth conditions.

The etch-back which is described in this invention may occur on one, multiple, or all faces of the seed crystal. Preferential etching of specific faces of the seed crystal may be accomplished by masking certain faces of the seed crystal which are not intended to be etched with a coating, such as a metallic coating. Furthermore, the etch-back of the source material may occur on one, multiple, or all surfaces or faces of the source material.

After the desired amount of etch-back has been achieved through the methods described in the previous paragraphs, it is possible to change the conditions within the reactor in such a fashion that the seed crystals are in a zone which has a lower solubility of the group-III element or compound than the source material zone. This in effect causes material to be transported from the source material to the seed crystals and can therefore growth may occur on the etched-back seed crystal. The conditions under which the growth occurs are subject to optimization and, as with the etch-back method described above, may contain multiple steps with varying conditions to achieve a high quality group-III nitride crystal grown on the etched-back seed crystal.

After growth, it is possible to cool the vessel and remove the group-III nitride crystals that have been grown. Any group-III nitride crystal material created through the process detailed in this invention, with any possible combination of vessel components, vessel configurations, conditions during etch-back, and conditions during growth, is part of the present invention.

Apparatus Description

The present invention provides a hexagonal würtzite type group-III nitride crystal grown on an etched-back seed crystal. The present invention also comprises a method for improving the crystal quality of a group-III nitride crystal grown on a seed crystal in supercritical nitrogen-containing solvent. In particular, the present invention utilizes the removal of material from the surface of the seed crystal and/or source material prior to growth of the group-III nitride crystal. It is preferable to start the growth of the group-III nitride crystal on a seed crystal with a surface that is composed of a single crystal grain and has no undesired chemical compounds, oxide layers, or other layers on it and preferentially using source material that has undesired chemical compounds, oxide layers and other undesired layers removed by means of etch-back prior to growth.

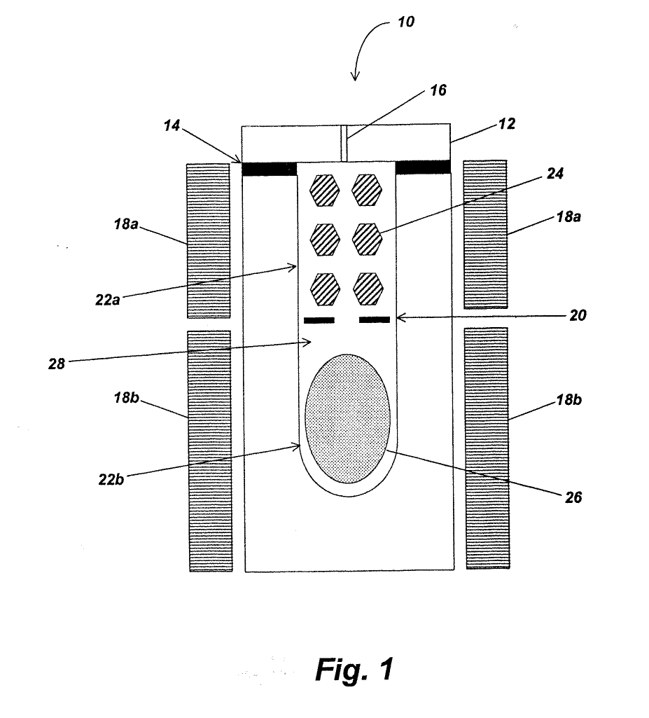

FIG. 1 is a schematic of an ammonothermal growth system comprising a high-pressure reaction vessel 10 according to one embodiment of the present invention. The vessel 10, which is a 1-inch diameter autoclave, may include a lid 12, gasket 14, inlet and outlet port 16, and external heaters/coolers 18a and 18b. A baffle plate 20 divides the interior of the vessel 10 into two zones 22a and 22b, wherein the zones 22a and 22b are separately heated and/or cooled by the external heaters/coolers 18a and 18b, respectively. An upper zone 22a may contain one or more group-III nitride seed crystals 24 and a lower zone 22b may contain one or more group-III-containing source materials 26, although these positions may be reversed in other embodiments. Both the group-III nitride seed crystals 24 and group-III-containing source materials 26 may be contained within baskets or other containment devices, which are typically comprised of an Ni—Cr alloy. The vessel 10 and lid 12, as well as other components, may also be made of a Ni—Cr based alloy. Finally, the interior of the vessel 10 is filled with a nitrogen-containing solvent 28 to accomplish the ammonothermal growth.

Process Description

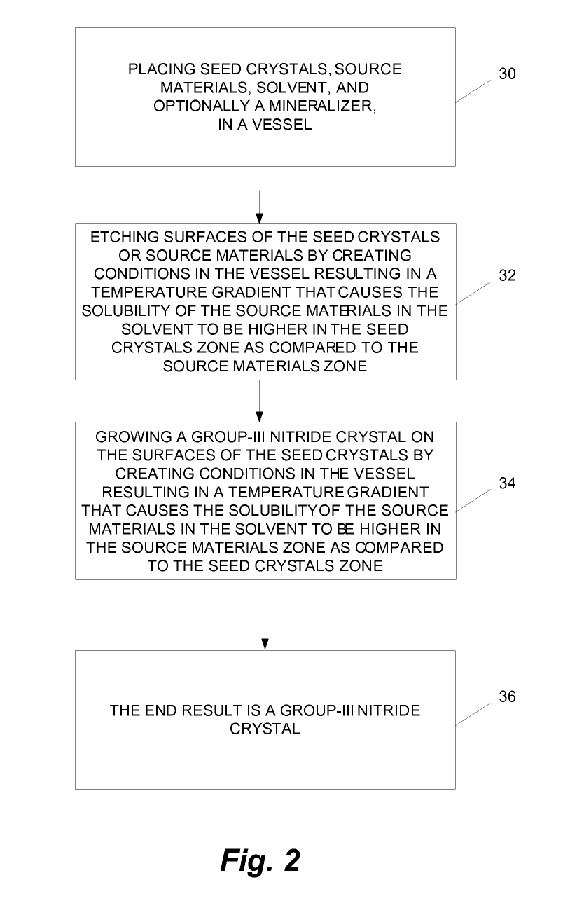

FIG. 2 is a flow chart illustrating a method for obtaining or growing a group-III nitride crystal according to one embodiment of the present invention.

Block 30 represents placing a nitrogen-containing solvent, one or more group-III-containing source materials, and one or more group-III seed crystals in the vessel 10, wherein the seed crystals are placed in a seed crystals zone (i.e., which may be either 22a or 22b, namely the opposite of the source materials zone) and the source materials are placed in a source materials zone (i.e., which may be either 22b or 22a, namely the opposite of the seed crystals zone). The source materials comprise a group-III-containing compound, a group-III element in its pure elemental form, or a mixture thereof, i.e., a group-III element, a group-III nitride monocrystal, a group-III nitride polycrystal, a group-III nitride powder, group-III nitride granules, or other group-III-containing compound; the seed crystals preferably comprise a group-III-containing single crystal; and the nitrogen-containing solvent comprises supercritical ammonia or one or more of its derivatives. An optional mineralizer may be placed in the vessel 10 as well, wherein the mineralizer increases the solubility of the source materials in the nitrogen-containing solvent as compared to the nitrogen-containing solvent without the mineralizer.

Block 32 represents creating one or more first conditions within the vessel 10 causing etch-back of one or more surfaces of the seed crystals or source materials, wherein the first conditions comprise forming a temperature gradient between the source materials and the seed crystals that causes a higher solubility of the source materials in the seed crystals zone and a lower solubility, as compared to the higher solubility, of the source materials in the source materials zone. Specifically, etching of the surfaces of the seed crystals occurs by heating the source materials zone to one or more source materials zone temperatures and heating the seed crystals zone to one or more seed crystals zone temperatures different than the source materials zone temperatures, to create a first temperature gradient between the source materials zone and the seed crystals zone that produces a higher solubility of the source materials in the supercritical nitrogen-containing solvent in the seed crystals zone as compared to the source materials zone. The etch-back or etching removes one or more monolayers from the seed crystals, and the etching step may occur before, after, or before and after the growing step that follows. In addition, there may be multiple etching steps, each with different temperatures, temperature gradients, and/or etching durations. The etch-back or etching of the surfaces results in material removed from the surfaces that includes spontaneously nucleated material, group-III nitride crystal of low crystalline quality, residual oxide layers, or chemical compounds other than the group-III nitride crystal. The etched surfaces may have any crystallographic orientation, including c-plane, nonpolar, and semipolar orientations.

Block 34 represents subsequently forming one or more second conditions causing growth of a group-III nitride crystal on one or more the surfaces of the seed crystals, wherein the second conditions comprise forming a temperature gradient between the source materials and the seed crystals that causes a higher solubility of the source materials in the source materials zone and a lower solubility, as compared to the higher solubility, of the source materials in the seed crystals zone. Specifically, growing the group-III nitride crystal on the surfaces of the seed crystals occurs by changing the source materials zone temperatures and the seed crystals zone temperatures to create a second temperature gradient between the source materials zone and the seed crystals zone that produces a higher solubility of the source materials in the nitrogen-containing solvent in the source materials zone as compared to the seed crystals zone.

In both Blocks 32 and 34, the source materials zone and seed crystals zone temperatures may range between 0° C. and 1000° C., and the first and second temperature gradients may range between 0° C. and 1000° C.

Block 36 comprises the resulting product created by the process, namely a group-III nitride crystal grown by the method described above. A group-III nitride substrate may be created from the group-III nitride crystal. A device may be created using the group-III nitride substrate.

Experimental Results In experiments performed by the inventors, a vessel was loaded with seed crystals (such as GaN substrates grown by HVPE methods) in a lower zone of the vessel (the seed crystals zone) and group-III-containing source materials (such as polycrystalline GaN crystals contained in a Ni—Cr mesh basket) in a upper zone (the source materials zone), and a baffle plate was set in the middle of the vessel to separate the lower zone from the upper zone. The polycrystalline GaN nutrient was synthesized by the HVPE method, but could be produced by any method. Next, mineralizer material, such as metallic sodium, was added to the vessel to increase the solubility of GaN in solution. The vessel was then closed. The previous loading processes were all performed inside a nitrogen glove box to avoid oxygen contamination and reaction of the metallic sodium with water vapor (per Block 30 of FIG. 2).

After closing and sealing the vessel, the vessel was cooled down using liquid nitrogen. Ammonia was then added into the vessel through a specialized port containing a high pressure valve. The amount of ammonia was monitored by a flow meter, and the high pressure valve was then closed after the necessary amount of ammonia was condensed inside the vessel 10. The amount of ammonia was strictly controlled so as to obtain the necessary pressure at the growth temperature, in this case ˜200 MPa at 500-600° C.

After filling the vessel with ammonia and allowing it to warm up to room temperature, the vessel was set within the resistive heating system. The heating system contains two separate zones which can be controlled independently, a lower zone and an upper zone, which correspond to the seed crystals zone and source materials zone, respectively.

The source materials zone temperature was maintained at 400° C.-600° C., and the seed crystals zone temperature was maintained at 400° C.-600° C., with a temperature gradient or difference between the two zones between 1° C. and 100° C. The temperature of the source materials zone was maintained at a higher temperature than the seed crystals zone. This temperature gradient produced a solubility difference between the two zones, causing etch-back of material on the seed crystal and transport of the group-III-containing source materials from the seed crystals zone to the source materials zone (per Block 32 of FIG. 2).

After maintaining these conditions for a period between 1 minute and 10 days, the direction of the temperature gradient between the two zones was reversed and temperatures were chosen such that the solubility of GaN in the source materials zone was higher than that of the seed crystals zone. The temperatures in this case were 475° C.˜575° C. for the source materials zone and 525° C.˜625° C. for the seed crystals zone. The gradient that is present not only produces a solubility gradient that encourages material growth on the etched seed crystals, but also enhances the convective flow of the solvent inside the vessel for improved nutrient transfer (per Block 34 of FIG. 2).

After the desired number of days passed during which the GaN grew on the seed crystals, the heaters were turned off and the vessel cooled. The vessel was then opened and the resulting crystals were removed (per Block 36 of FIG. 2).

Having grown a GaN crystal according to the method described above, the crystal may then be analyzed using X-ray techniques. These techniques allow the present invention to determine the crystal quality of the crystal being analyzed. One such technique involves placing the crystal in a X-ray Diffraction (XRD) tool and positioning the crystal in such a manner that an intensity peak in the diffracted x-rays occurs for a particular plane of interest. The crystal is then rocked back and forth and the intensity should drop. The resulting plot of intensity versus angle, also called an omega rocking curve, may have the form of a Gaussian and the width, or more precisely the Full Width at Half Maximum (FWHM), of this bell shaped curve is representative of the crystal quality in that particular direction of the crystal. The narrower the bell shaped curve is, the higher the crystal quality.

By performing an omega rocking curve scan for the (0 0 0 2) planes, or c-plane, on the various facets of the hexagonal würtzite GaN crystal, values were found to be between 40 arcsec and 413 arcsec, with the value dependent on which particular facet was analyzed. Typical values for GaN crystals grown by this technique without etch-back were found to range from 90 arcsec to 2771 arcsec.

Similar scans were also performed on semi-polar (1 0 2) planes on the various facets of the hexagonal würtzite GaN crystal. Values for the scans on the semi-polar planes were found to be between 55 arcsec and 135 arcsec, with the value dependent on which particular facet was analyzed. Typical values for GaN crystals grown by this technique without etch-back were found to range from 78 arcsec to 618 arcsec. Clearly, the act of etching back the surface of the seed crystal prior to growth resulted in an improvement in the crystal quality of the grown GaN.

To verify that etch-back occurred, the etch-back step was performed under identical conditions and then the heaters were turned off without having a growth period. The thickness of the seed crystals was measured and it was found that all the seed crystals were 1 to 30 micrometers thinner than when they were placed into the vessel. Further, it is possible to look at the seed crystals using various microscopy methods such as scanning electron microscopy (SEM) and regular light microscopy and it was found that the smooth surface of the seed crystal changed to a rougher surface with different surface features depending on the facet being analyzed. Thus, in combination with a reduction in thickness, it was concluded that etch-back did indeed occur and is the underlying cause for the improved crystal quality.

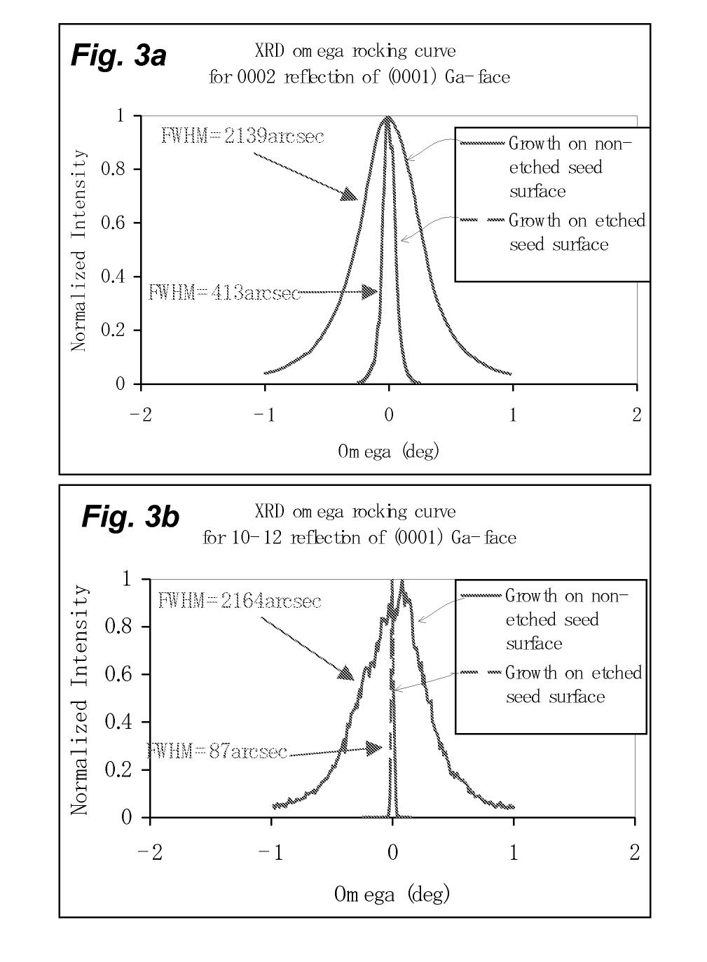

FIG. 3a is a graph that illustrates the XRD omega rocking curve for 0002 reflections of the (0001) Ga-face, and FIG. 3b is a graph that illustrates the XRD omega rocking curve for 10-12 reflections of the (0001) Ga-face.

Possible Modifications and Variations

The preferred embodiment has described one example of a method to etch-back the seed crystal prior to growth of a group-III nitride material on the seed crystal. Although GaN growth on etched-back seeds was described, the present invention is suitable for the growth of all group-III nitride crystals and epitaxial layers, including BN, AlN, GaN, InN and their alloys such as BInN and AlGaInN. Additionally, the group-III nitride crystal which is grown may contain other elements from any group of the periodic table of elements. For example, doping elements may be included in the supercritical nitrogen-containing solvent and/or source material, including but not limited to silicon (Si) and magnesium (Mg).

The present invention has used GaN seed crystals but any seed crystal, including but not limited to BN, AlN, GaN, InN, alloys thereof, sapphire, and SiC may be used according to the present invention. Additionally, the method of growth chosen for the seed crystal is not restricted to HVPE as presented in the example, but may be of any known method, including but not limited to, MOCVD, MBE, PVT, HPSG, flux method, and ammonothermal methods.

The present invention describes one particular configuration of the autoclave and dividing it horizontally into an upper and lower zone. This has been used for illustrative purposes only and the autoclave can be configured in any fashion, as long as one zone is separated from the other. This may include, but is not limited to, configurations where the two zones are horizontally and/or vertically separated. Additionally, more than two zones with different temperatures may be used according the present invention. The present invention only requires reactor zones and conditions that can facilitate dissolution of a seed crystal prior to film growth.

Although the present invention has repeatedly used hexagonal würtzite GaN, it should not be considered restrictive in any manner and any crystal structure for GaN and any possible group-III nitride, for example AlGaN, InGaN, BGaN, BInN, AlGaInN, is included in the present invention, including, to but not limited to, the hexagonal würtzite and cubic zincblende structures.

The present invention has made use of certain conditions, including but not limited to, the duration of etch-back, amount of etch-back, rate at which etch-back occurs, temperatures of the seed crystals, temperature gradients, total pressure of the system, amount of supercritical nitrogen-containing solvent, and number of etch-back steps. These conditions along with other conditions that have not been mentioned are subject to optimization, and the present invention includes any possible combination and values for these parameters.

The present invention has stated that the crystal quality of the newly grown group-III nitride crystal is of comparable quality to that of the seed crystal. This should not be considered limiting and conditions may be found under which application of this method allows for the improvement of the crystal quality of the grown group-III nitride crystal to qualities better than that of the seed crystal. In fact, preliminary experiments have shown that the growth of thick layers on seed crystals results in layers with improved structural quality as compared to the seed crystals.

The preferred embodiment of the present invention has utilized etching of all surfaces of the seed crystals. According to the present invention, however, any or all surfaces of the seed crystal may be etched. In many applications it is desirable to etch all surfaces of the seed crystal, but the present invention is also applicable to the etching of any number of surfaces of the seed crystal. For example, all but one surface of the seed crystal may be covered to cause etching of only one surface of the seed crystal.

The seed crystals used in the present invention may be of any composition and structural quality. They may be composed of a single crystalline grain or composed of multiple grains. The structural qualities and attributes of the seed crystal are not of critical importance to the present invention.

The supercritical nitrogen-containing solvent may be a single nitrogen-containing solvent or a combination of two or more nitrogen-containing solvents. Additionally, other solvents that do not include nitrogen may also be added to the nitrogen-containing solvent(s) according to the present invention.

Although polycrystalline GaN was used a source material in the present invention, the source material may be any Ga-containing material or compound, including but not limited to Ga metal and amorphous GaN.

Although Na metal was used a mineralizer in the present invention, any mineralizer or combination of mineralizers may be used, including neutral, acidic, and basic mineralizers.

Advantages and Improvements

There are a variety of methods being pursued for the growth of hexagonal würtzite single crystals which are to be used as substrates for epitaxial growth. Some of these approaches are in the research and development phase, while others have already been industrialized. In most approaches, a crystal is grown on a previously existing crystal that may or may not be identical to the layer being grown on it, for example, in the sodium flux method, GaN is grown on a GaN seed crystal, or in the hydrothermal growth of ZnO or quartz, a seed crystal made of ZnO or quartz, respectively, is grown upon. Improving the quality of the grown layer is key to obtaining a high quality crystal which can then be used for various purposes. The higher quality the crystal is and the fewer dislocations and pits that are present, the better the performance of the device and its associated electrical properties.

The present invention has found that by removing undesired material from the surface of the seed crystals prior to growing on them, the crystal quality of the grown group-III nitride material is significantly improved and is comparable to the crystal quality of the substrate. This material and method enables substrates to be created that possess superior quality for the subsequent epitaxial growth of devices with reduced dislocation densities and sub-grains, thereby enabling high-quality devices to be produced with high reliability.

### REFERENCES

The following references are incorporated by reference herein.

[1] Jpn. J. Appl. Phys. 45 (2006) pp. 739-741.

[2] Appl. Phys. Lett. 87 (2005) 231110.

[3] J. Mater. Sci. 41 (2006) 1399-1407.

[4] J. Crystal Growth 308 (2007) 71-79.

[5] Jap. J. Appl. Phys. 44 (2005), L797-L799.

[6] J. Crystal Growth 305 (2007) 311-316.

[7] S. Cruz et al., “Crystallographic orientation dependence of dopant and impurity incorporation in GaN films grown by metalorganic chemical vapor deposition,” J. Crystal Growth, Volume 311, Issue 5, 15 Jul. 2009, pp. 3817-3823.

Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of growing group-III nitride crystals in a vessel, comprising:
(a) containing in the vessel:
(1) one or more group-III-containing source materials in a source materials zone,
(2) one or more seed crystals in a seed crystals zone, and
(3) a nitrogen-containing solvent;
(b) etching one or more surfaces of the seed crystals or the source materials; and
(c) growing the group-III nitride crystals on the seed crystals.

2. The method of claim 1, wherein the etching step (b) is performed by heating the source materials zone to one or more source materials zone temperatures and heating the seed crystals zone to one or more seed crystals zone temperatures.

3. The method of claim 2, wherein the seed crystals zone temperatures are different than the source materials zone temperatures to create a first temperature gradient between the source materials zone and the seed crystals zone that produces a higher solubility in the seed crystals zone as compared to the source materials zone.

4. The method of claim 3, wherein the growing step (c) is performed by changing the source materials zone temperatures and the seed crystals zone temperatures to create a second temperature gradient between the source materials zone and the seed crystals zone that produces a higher solubility in the source materials zone as compared to the seed crystals zone.

5. The method of claim 4, wherein the first and second temperature gradients are between 0° C. and 1000° C.

6. The method of claim 2, wherein the source materials zone and seed crystals zone temperatures are between 0° C. and 1000° C.

7. The method of claim 1, wherein the etching step (b) occurs before, after, or before and after the growing step (c).

8. The method of claim 1, wherein the etching step (b) removes one or more monolayers from the seed crystals.

9. The method of claim 1, wherein the surfaces are exposed surfaces that have any crystallographic orientation, including c-plane, nonpolar, and semipolar orientations.

10. The method of claim 1, wherein the source materials comprise a group-III-containing compound, a group-III element in its pure elemental form, or a mixture thereof

11. The method of claim 1, wherein the seed crystals comprise a group-III-containing single crystal.

12. The method of claim 1, wherein the nitrogen-containing solvent is supercritical ammonia or one or more of its derivatives.

13. The method of claim 1, further comprising containing a mineralizer in the vessel, wherein the mineralizer increases solubility in the nitrogen-containing solvent as compared to the nitrogen-containing solvent without the mineralizer.

14. A group-III nitride crystal grown by the method of claim 1.

15. A group-III nitride substrate created from the group-III nitride crystal of claim 14.

16. A device created using the group-III nitride substrate of claim 15.

17. A method of obtaining group-III nitride crystals, comprising:
placing a nitrogen-containing solvent, one or more group-III-containing source materials, and one or more seed crystals in a vessel;
forming one or more first conditions within the vessel causing etch-back of one or more surfaces of the seed crystals or the source materials; and
forming one or more second conditions causing growth of the group-III nitride crystals on the surfaces of the seed crystals.

18. The method of claim 17, wherein the etching step (b) occurs before, after, or before and after the growing step (c).

19. The method of claim 17, wherein the first and second conditions comprise forming a temperature gradient between the source materials and the seed crystals.

20. The method of claim 19, wherein the first condition comprises forming a temperature gradient that causes a higher solubility in a seed crystals zone and a lower solubility, as compared to the higher solubility, in a source materials zone.

21. The method of claim 19, wherein the second condition comprises forming a temperature gradient that causes a higher solubility in a source materials zone and a lower solubility, as compared to the higher solubility, in a seed crystals zone.

22. The method of claim 17, wherein the surfaces are exposed surfaces that have any crystallographic orientation, including c-plane, nonpolar, and semipolar orientations.

23. The method of claim 17, wherein the nitrogen-containing solvent is supercritical ammonia or one or more of its derivatives.

24. The method of claim 17, wherein the source materials comprise a group-III-containing compound, a group-III element in its pure elemental form, or a mixture thereof.

25. The method of claim 17, wherein the seed crystals comprise group-III-containing crystals.

26. The method of claim 25, wherein the etch-back of the surfaces of the seed crystals or source materials results in material removed from the seed crystals or source materials that includes spontaneously nucleated material, group-III nitride crystal of low crystalline quality, residual oxide layers, or chemical compounds other than the group-III nitride crystal.

27. The method of claim 17, wherein the growth of the group-III nitride crystals on the surfaces of the seed crystals suppresses formation of multiple grains during the growth.

28. The method of claim 17, wherein the source materials comprise a group-III nitride monocrystal, a group-III nitride polycrystal, a group-III nitride powder, group-III nitride granules, or other group-III-containing compound.

29. The method of claim 17, wherein the vessel contains one or more zones that have objects, material, walls, or other sites that serve as surfaces or sites for precipitation of the source materials from the nitrogen-containing solvent.

30. The method of claim 17, further comprising placing a mineralizer in the vessel, wherein the mineralizer increases the solubility of the source materials in the nitrogen-containing solvent as compared to the nitrogen-containing solvent without the mineralizer.

31. A group-III nitride crystal grown by the method of claim 17.

32. A group-III nitride substrate created from the group-III nitride crystal of claim 31.

33. A device created using the group-III nitride substrate of claim 32.
